(19) United States
(12) Patent Application Publication
(10) Pub. No.: US 2017/0356079 A1
(43) Pub. Date: Dec. 14, 2017

(54) LINEAR EVAPORATION SOURCE

(71) Applicant: KUNSHAN GO-VISIONOX OPTO-ELECTRONICS CO., LTD., Jiangsu (CN)

(72) Inventors: Chao-Chi PENG, Jiangsu (CN); Shenfu ZHANG, Jiangsu (CN)

(73) Assignee: KUNSHAN GO-VISIONOX OPTO-ELECTRONICS CO., LTD., Jiangsu (CN)

(21) Appl. No.: 15/540,571

(22) PCT Filed: Dec. 21, 2015
(86) PCT No.: PCT/CN2015/097995

§ 371 Date: Jun. 28, 2017

(30) Foreign Application Priority Data
Dec. 29, 2014 (CN) 201410831691.X

(51) Int. Cl. C23C 14/24; H01L 51/00; C23C 14/54

(52) U.S. Cl. CPC C23C 14/24; C23C 14/542; H01L 51/001

(57) ABSTRACT

The present invention provides a linear evaporation source, comprising: a heating chamber for containing a vapor deposition material, a mixing chamber located above the heating chamber and used to mix the vapor deposition material vapor, and a channel used to communicate the heating chamber and the mixing chamber, wherein one end of the mixing chamber communicates with the heating chamber through the channel, and the other end is provided with a plurality of nozzles for spraying the vapor deposition material vapor; and heaters are provided at peripheries of the heating chamber, the mixing chamber, the channel and the nozzles. The linear evaporation source of the present invention can control the thickness of the vapor deposition film to have a better uniformity, because the heating of the vapor deposition material and the mixing of the material vapor are conducted in two independent spaces.

### TECHNICAL FIELD

The present invention relates to an evaporation source, and particularly relates to a linear evaporation source which can ensure the uniformity of the thickness of a vapor deposition film.

### BACKGROUND ART

In the manufacturing process of OLED (Organic Light Emitting Diode), with the size of vapor deposition substrate bigger, in order to ensure the uniformity of the thickness of the vapor deposition film, and to improve material utilization, the evaporation sources used by vapor deposition equipments have been developed to linear sources from the original point sources.

As shown in FIGS. 1 and 2, the current linear sources generally comprise a crucible 1 and more than one nozzle 2 above the crucible 1. Heating wires 3 are provided at the peripheries of the crucible 1 and the nozzles 2, inside which the vapor deposition material can become vapor, and then the vapor is sprayed out to the substrate to form a film after being uniform inside the crucible 1, by heating the crucible 1.

In current linear evaporation sources, because the heating of the vapor deposition material and the mixing of the vapor are simultaneously conducted in the crucible, the space for the mixing and uniformization of the vapor is limited, the material vapor trends to be sprayed from the nozzles before becoming uniform, which in turn results in the degrading of the uniformity of the thickness of the vapor deposition film. Especially for the crucibles just filled with the material, the space that can be used for the material vapor to equilibrium the pressure is more limited, which has greater influence on the uniformity of the thickness of the vapor deposition film. Furthermore, the heating wires of the current evaporation sources are sectional heating, which is a complex heating mode.

### TECHNICAL PROBLEM

In view of that, the main purpose of the present invention is to provide a linear evaporation source which can make the thickness of the vapor deposition film to be uniform.

### Technical Solution

To achieve the above purpose, the present invention provides a linear evaporation source, comprising a heating chamber for containing a vapor deposition material, a mixing chamber located above the heating chamber and used to mix the vapor deposition material vapor, and a channel used to communicate the heating chamber and the mixing chamber; one end of the mixing chamber communicates with the heating chamber through the channel, and the other end is provided with a plurality of nozzles for spraying the vapor deposition material vapor; and heaters are provided at peripheries of the heating chamber, the mixing chamber, the channel and the nozzles.

The channel is composed of a plurality of channels.

The plurality of channels are evenly arranged between the heating chamber and the mixing chamber.

A middle plate that the vapor deposition material vapor can permeate is provided within the channel, and the middle plate is clamped at an inner wall of the channel.

The middle plate is provided with a plurality of through holes.

The shape of the edge of the middle plate is zigzag-shaped.

The channel is provided with a valve for controlling a flowing speed and a flow rate of the vapor deposition material vapor that flows through.

The heaters are heating wires evenly wound at the peripheries of the heating chamber, the mixing chamber, the channel or the nozzles.

The heating wires wound at the peripheries of the heating chamber, the mixing chamber, the channel and the nozzles are integrally formed.

The heaters provided at the peripheries of the heating chamber, the mixing chamber, the channel and the nozzles are heating plates.

### Advantageous Effects

The linear evaporation source of the present invention can control the thickness of the vapor deposition film to have a better uniformity, because the heating of the vapor deposition material and the mixing of the material vapor are conducted in two independent spaces. The heaters provided at the peripheries of the heating chamber, the mixing chamber, the channel and the nozzles can heat simultaneously, without sectional heating, so as to simplify the heating mode.

### BRIEF DESCRIPTION OF THE DRAWINGS

FIG. 1 is the structural schematic diagram of a linear evaporation source in the prior art;

FIG. 2 is the side view of FIG. 1;

FIG. 3 is the structural schematic diagram of the linear evaporation source according to the present invention;

FIG. 4 is the side view of FIG. 3;

FIG. 5 is the structural schematic diagram of another embodiment of the linear evaporation source according to the present invention; and

FIG. 6 is the side view of FIG. 5.

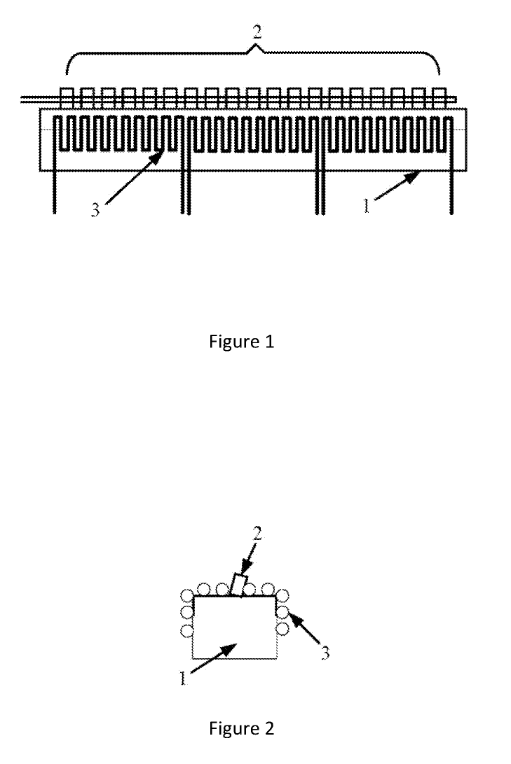

### DETAILED DESCRIPTION OF PREFERRED EMBODIMENTS

In order to facilitate the further understanding of the structure and the effects of the present invention, a detailed description is made by referring to the drawings and the preferred embodiments.

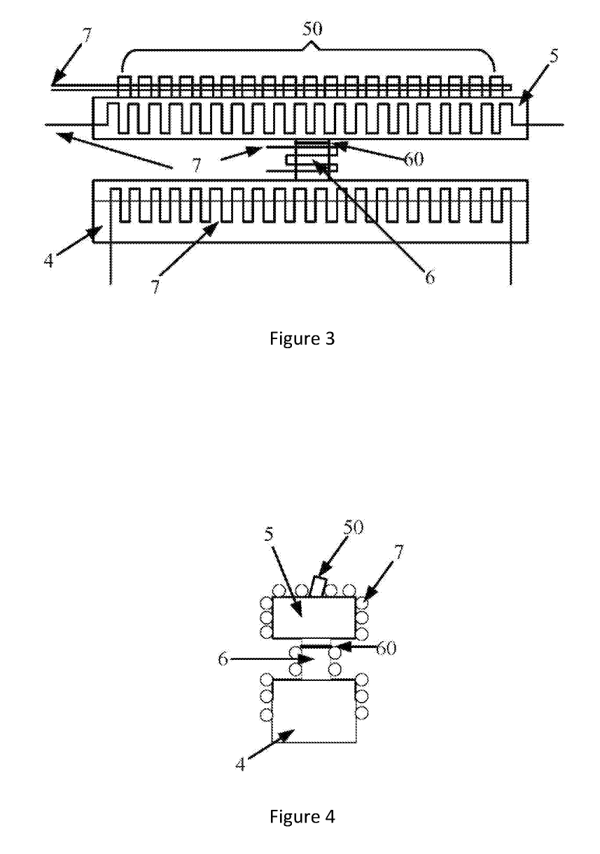

As shown in FIGS. 3 and 4, the linear evaporation source of the present invention comprises: a heating chamber 4, a mixing chamber 5 located above the heating chamber 4, and a channel 6 used to connect the heating chamber 4 and the mixing chamber 5, wherein one end of the mixing chamber 5 communicates with the heating chamber 4 through the channel 6, and the other end is provided with a plurality of nozzles 50. Heaters 7 are provided at the peripheries of the heating chamber 4, the mixing chamber 5, the channel 6 and the nozzles 50.

When the substrate is evaporation deposited by the linear evaporation source of the present invention, the vapor deposition material are placed inside the heating chamber 4, whose corresponding parts are heated by the heaters 7 provided at the peripheries of the heating chamber 4, the mixing chamber 5, the channel 6, and the nozzles 50. Then the vapor deposition material melt in the heating chamber 4 and vaporize into vapor deposition material vapor, or directly gasify into vapor deposition material vapor, which enters the mixing chamber 5 through the channel 6. Because the mixing of the vapor deposition material vapor is only done in the mixing chamber 5, the vapor deposition material vapor can balance the pressure in the mixing chamber 5, and the vapor deposition material vapor is sprayed from the nozzles 50 after homogeneous mixing, which can ensure forming the uniform thickness vapor deposition film on the substrate, so that vapor deposition on the substrate has been accomplished. The plurality of nozzles 50 of the present invention may be evenly arranged on the mixing chamber 5, so that the vapor deposition material vapor can be evenly sprayed from the nozzles 50, so as to form the vapor deposition film with more uniform thickness.

A middle plate 60 may be disposed inside the channel 6 between the heating chamber 4 and the mixing chamber 5 of the present invention, wherein the middle plate 60 with more than one through holes is clamped on the inner wall of the channel 6, so that the middle plate 60 can prevent the unevaporated melted liquid from being sprayed into the mixing chamber 5 after the vapor deposition material have been melted in the heating chamber 4. Furthermore, before entering the mixing chamber 5, the vapor deposition material vapor inside the heating chamber 4 meets the middle plate 60, which has certain resistance on the vapor deposition material vapor, so that the vapor deposition material vapor can be evenly mixed primarily by the middle plate 60, and then evenly mixed in the mixing chamber 5 again, so as to further ensure the uniformity of the thickness of the vapor deposition film formed on the substrate. The shape of the edge of the middle plate 60 may be zigzag-shaped in the present invention. The vapor deposition material vapor can enter the mixing chamber 5 through the zigzag-shaped interspace between the middle plate 60 and the inner wall of the channel 6. The middle plate 60 can prevent the unevaporated melted liquid from being sprayed into the mixing chamber 5, and can evenly mix the vapor deposition material vapor primarily before entering the mixing chamber 5.

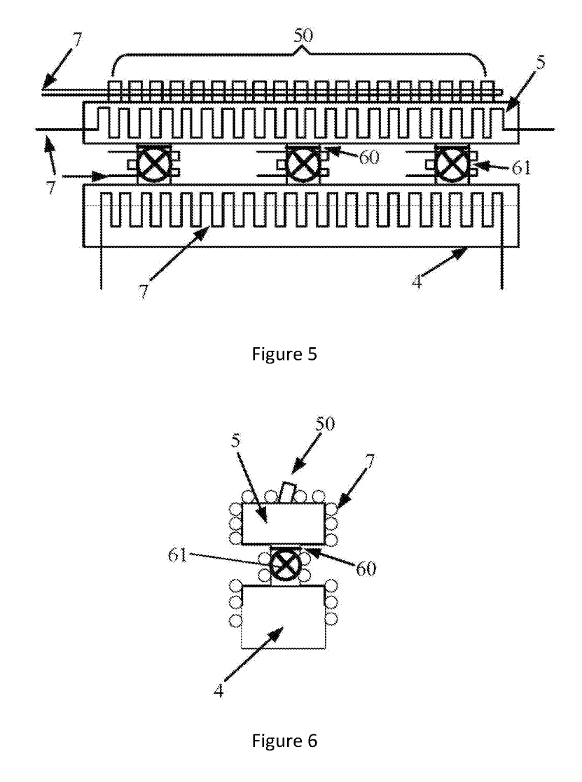

As shown in FIGS. 5 and 6, in the present invention there may be a plurality of channels 6 between the heating chamber 4 and the mixing chamber 5, which are evenly arranged between the heating chamber 4 and the mixing chamber 5. Each of the channels 6 may be provided with a valve 61, which can control the flowing speed and flow rate of the vapor deposition material vapor flowing through each of the channels 6, so that the vapor deposition material vapor in the mixing chamber 5 can become more uniformly. As an example, if more vapor deposition material is corresponding to a certain channel in the heating chamber 5, more vapor deposition material vapor can be generated, so that the flowing speed is quick and the flux is flow rate when the vapor deposition material vapor is flowing through the channel, then the valve on the channel can be controlled to control the flowing speed and flow rate of the vapor deposition material vapor flowing through the channel.

In the present invention, the heaters 7 may be heating wires evenly wound at the peripheries of the heating chamber 4, the mixing chamber 5, the channel 6 and the nozzles 50, so can evenly enough heat the vapor deposition material in the heating chamber 4 and the vapor deposition material vapor flowing through the channel 6, the mixing chamber 5 and the nozzles 50, so as to control the uniformity of the thickness of the vapor deposition film on the substrate. The heating wires wound at the peripheries of the heating chamber 4, the mixing chamber 5, the channel 6 and the nozzles 50 may be integrally formed. The heaters 7 of the present invention may also be heating plates for heating the corresponding heating chamber 4, mixing chamber 5, channel 6 and nozzles 50, whose temperatures can be adjusted according to actual circumstances.

The linear evaporation source of the present invention can control the thickness of the vapor deposition film to have a better uniformity, because the heating of the vapor deposition material and the mixing of the vapor deposition material vapor are conducted in two independent spaces of the heating chamber 4 and the mixing chamber 5. The heating wires of the present invention wound at the peripheries of the heating chamber 4, the mixing chamber 5, the channel 6 and the nozzles 50 may be integrally formed, without sectional heating, so as to simplify the heating mode.

The above description is only preferred embodiments of the present invention, and is not intended to limit the protection scope of the present invention.

What is claimed is:

1. A linear evaporation source, characterized by: comprising: a heating chamber for containing a vapor deposition material, a mixing chamber located above the heating chamber and used to mix the vapor deposition material vapor, and a channel used to communicate the heating chamber and the mixing chamber, wherein one end of the mixing chamber communicates with the heating chamber through the channel, and the other end is provided with a plurality of nozzles for spraying the vapor deposition material vapor; and heaters are provided at peripheries of the heating chamber, the mixing chamber, the channel and the nozzles.

2. The linear evaporation source as claimed in claim 1, characterized in that: the channel is composed of a plurality of channels.

3. The linear evaporation source as claimed in claim 2, characterized in that: the plurality of channels are evenly arranged between the heating chamber and the mixing chamber.

4. The linear evaporation source as claimed in claim 1, characterized in that: a middle plate that the vapor deposition material vapor can permeate is provided within the channel, and the middle plate is clamped at an inner wall of the channel.

5. The linear evaporation source as claimed in claim 1, characterized in that: the middle plate is provided with a plurality of through holes.

6. The linear evaporation source as claimed in claim 4 or 5, characterized in that: the shape of the edge of the middle plate is zigzag-shaped.

7. The linear evaporation source as claimed in any of claims 1-5, characterized in that: the channel is provided with a valve for controlling a flowing speed and a flow rate of the vapor deposition material vapor that flows through.

8. The linear evaporation source as claimed in claim 1, characterized in that: the heaters are heating wires evenly wound at the periphery of the heating chamber, the mixing chamber, the channel or the nozzles.

9. The linear evaporation source as claimed in claim 8, characterized in that: the heating wires wound at the peripheries of the heating chamber, the mixing chamber, the channel and the nozzles are integrally formed.

10. The linear evaporation source as claimed in claim 8, characterized in that: the heaters provided at the peripheries of the heating chamber, the mixing chamber, the channel and the nozzles are heating plates.
